(19) United States
(12) Patent Application Publication
(10) Pub. No.: US 2015/0260796 A1
(43) Pub. Date: Sep. 17, 2015

(54) BATTERY CELL STATE-OF-CHARGE ESTIMATION AND READJUSTMENT METHOD

(71) Applicants: Commissariat à l'énergie atomique et aux énergies alternatives, Paris (FR); Decathlon, Villeveuve D'Ascq (FR)

(72) Inventors: Laurent VINIT, Le Bourget Du Lac (FR); Fathia KAROUI, Villeurbanne (FR); Ghislain DESPESSE, Voreppe (FR); Sébastien BRULAIS, Saint-Martin-d'H'eres (FR); Jean-Philippe GROS, Le Fontanil Cornillon (FR)

(21) Appl. No.: 14/658,557

(22) Filed: Mar. 16, 2015

(30) Foreign Application Priority Data
Mar. 17, 2014 (FR) 1452181

(51) Int. Cl. G01R 31/36

(52) U.S. Cl. CPC G01R 31/362

(57) ABSTRACT

A method of detecting a predetermined specific value of the charge contained in a first elementary cell of a battery, including the steps of: measuring the voltage across the cell under reference current at a plurality of times in a phase of cell charge or discharge between first and second state-of-charge levels; and detecting a predetermined specific value of this voltage, corresponding to the specific charge value.

The present patent application claims the priority benefit of French patent application FR14/52181, filed on Mar. 17, 2014, the contents of which are incorporated herein by reference in its entirety to the maximum extent allowable by law.

### BACKGROUND

The present disclosure generally relates to the field of electric batteries, and more particularly aims at detecting the crossing by an elementary battery cell of a predetermined specific charge value. It also aims at estimating the state of charge of an elementary battery cell and at readjusting this estimate.

### DISCUSSION OF THE RELATED ART

An electric battery is a group of a plurality of rechargeable elementary cells (cells, accumulators, etc.) connected in series and/or in parallel between two voltage supply nodes or terminals.

In certain systems, the state of charge, SOC, of each elementary cell of the battery, that is, the ratio of the charge contained in the cell to the total capacity of the cell at the considered time, is desired to be known at any time. To achieve this, a state-of-charge gauge (or indicator) may be associated with each battery cell. The gauges of the elementary cells may be managed by a battery management device, which estimates the state of charge of each cell based on predefined algorithms and measurements performed by sensors connected to the battery cells.

With known state-of-charge estimation solutions, a degradation of the estimate over time and as the battery cells age can generally be observed. To overcome this phenomenon, it is known to implement so-called phases of readjustment of a state-of-charge gauge, which comprise adapting the estimation algorithms, for example, by modifying parameters of these algorithms, to allow them to keep on providing a relatively reliable estimate. Generally, known state-of-charge gauge readjustment methods comprise fully charging or discharging the cell, and then, when an end of charge or an end of discharge is detected, adapting the estimation algorithms to reposition the state-of-charge gauge to 1000 or 0%. A disadvantage of such solutions is that they require implementing a full charge or discharge of the cell, which is relatively constraining and may be a problem in certain applications.

Patent application EP1562048 describes a method for measuring the capacity of a battery.

### SUMMARY

Thus, an embodiment provides a method of detecting a predetermined specific value of the charge contained in a first elementary cell of a battery, comprising the steps of: measuring the voltage across the cell at a plurality of times in a phase of cell charge or discharge between first and second state-of-charge levels; and detecting a predetermined specific value of this voltage, corresponding to the specific charge value, the specific charge and voltage values corresponding to the coordinates of a crossing point of at least two curves representative of the variation of the voltage according to the charge contained in the cell, for different cell states of health.

According to an embodiment, the voltage is the voltage across the cell under a reference current.

According to an embodiment, the specific charge and voltage values correspond to the coordinates of a crossing point of at least three curves representative of the variation of the voltage according to the charge contained in the cell, for different cell states of health.

According to an embodiment, the specific charge value is in the range from 20% to 60% of the nominal full charge capacity of the cell.

According to an embodiment, the cell is a lithium-ion type cell and the specific charge value is in the range from 38% to 42% of the nominal full charge capacity of the cell.

According to an embodiment, the cell has a 2.2-Ah nominal capacity and a 4.2-V nominal full charge voltage, and the specific voltage value is in the range from 3.5 to 3.6 V.

According to an embodiment, the method further comprises a previous characterization phase comprising acquiring, for a second elementary cell of same type as the first cell, at least two characteristic curves representative of the variation of the voltage across the second cell according to the charge contained in the second cell, for at least two different states of health of the second cell.

According to an embodiment, the previous characterization phase further comprises a step of determining a crossing point of the two characteristic curves in the charge range from 20% to 60% of the nominal cell capacity.

Another embodiment provides a method of assessing the state of charge of an elementary cell of a battery, comprising at least a phase of estimation of the state of charge of the cell by a state-of-charge estimation algorithm, and at least one phase of readjustment of the estimation algorithm, the readjustment phase comprising the steps of: detecting a predefined specific value of the charge contain in the cell by a method of the above-mentioned type; and readjusting the state-of-charge estimation algorithm by taking into account the difference between the specific charge value and a charge value estimated by the estimation algorithm at a time of detection of the specific charge value.

Another embodiment provides a system comprising: a battery comprising a plurality of elementary cells and a battery management device, wherein the management device is capable of detecting the crossing by an elementary cell of a predetermined specific charge value by a method of the above-mentioned type.

According to an embodiment, the battery is a battery having a dynamically reconfigurable architecture, and the management device is capable of dynamically disconnecting and connecting back battery cells so that an AC voltage is provided across the battery.

According to an embodiment, the reference current is zero, and the steps of measuring the voltage across the first cell are implemented for periods of disconnection of the first cell by the management device to generate an AC voltage across the battery.

The foregoing and other features and advantages will be discussed in detail in the following non-limiting description of specific embodiments in connection with the accompanying drawings.

### BRIEF DESCRIPTION OF THE DRAWINGS

FIG. 1 is a diagram illustrating the variation as it ages of the behavior of an elementary battery cell; and

FIG. 2 illustrates in the form of blocks an embodiment of a method of readjusting a state-of-charge gauge of an elementary battery cell.

### DETAILED DESCRIPTION

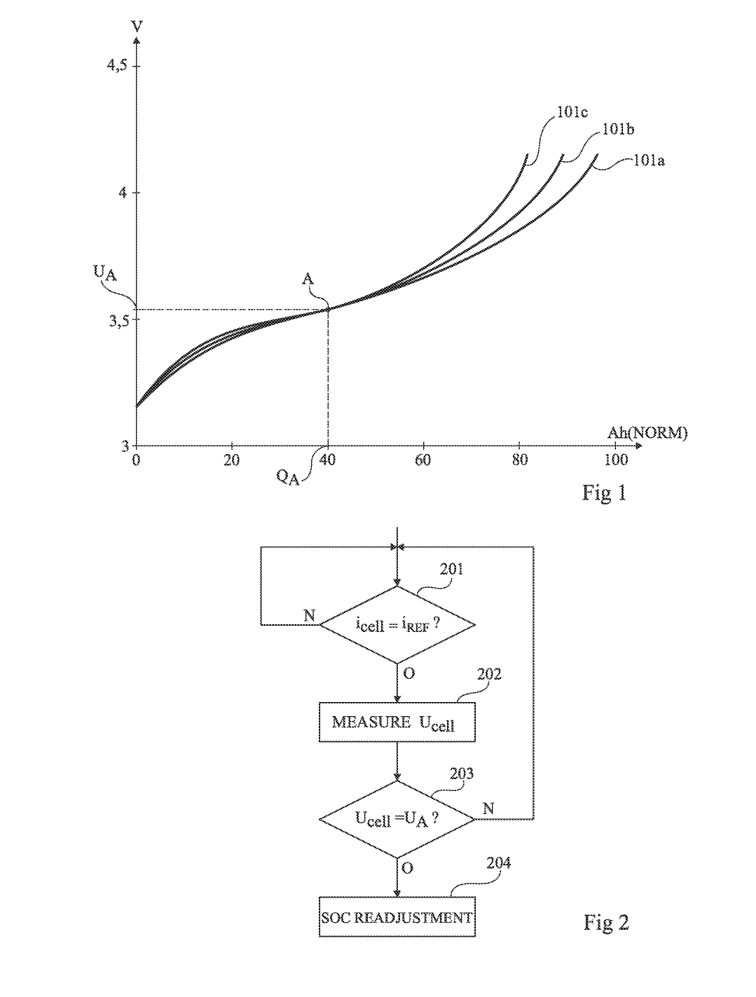

FIG. 1 is a diagram comprising three curves 101a, 101b, and 101c showing, for three different aging states or states of health of a battery cell, the variation of voltage U_{cell} in volts (V) across the cell under a reference current i_{ref} (that is, the voltage across the cell when the cell conducts current i_{ref}), according to the charge contained in the cell. The curves of FIG. 1 have been drawn for a lithium-ion cell of NMC (nickel cobalt manganese)/graphite type, having a 2.2-Ah nominal capacity (that is the capacity displayed by the manufacturer), and a 4.2-V nominal full charge voltage. Curve 101a shows the behavior of the cell when new, curve 101b corresponds to the same cell after approximately 600 charge/discharge cycles representative of a typical use of the cell, and curve 101c corresponds to the same cell after approximately 1,200 discharge/charge cycles representative of a typical use of the cell. In this example, the voltage measurements have been made under a zero reference current i_{ref}. Further, in FIG. 1, the cell charge, in abscissa, has been represented in remaining normalized amperes-hour (Ah NORM), that is, as a percentage of the nominal cell capacity. It thus really is a variable representative of the physical charge effectively contained in the cell (or number of remaining Ah), and not of the state of charge (SOC) of the cell, which is a percentage of the real total capacity of the cell, which may vary as the cell ages. Tests carried out by the inventors have shown that the curves characteristic of the voltage across the cell, under a constant reference current, according to the cell charge, at the different cell states of health, are all monotonous (that is, continuously increasing or decreasing) in the cell operating range and all cross at a same point characteristic of the cell, here designated with reference A. In the specific example of FIG. 1, point A corresponds to a 3.55-V voltage U_{A} and a charge Q_{A} of 40% of the nominal cell capacity (that is, 0.88 Ah in this example).

Tests carried out by the inventors have further shown that a similar behavior can be observed when the voltage measurements are made under a non-zero reference current i_{ref}, for example, a negative current—that is, a cell discharge current -or a positive current—that is, a cell charge current. In this case, coordinates U_{A} and Q_{A} of point A may change with respect to the example of FIG. 1, but the same phenomenon as in the example of FIG. 1 occurs, that is, all the characteristic voltage/charge curves at different cell states of health cross at a same point A.

The inventors have further observed that this same phenomenon can be observed for other types of cells than the lithium-ion cells of the example of FIG. 1, for example, lithium-ion cells having a nominal capacity different from 2.2 Ah and/or a nominal full charge voltage different from 4.2 V, or cells having a different chemistry, provided for these cells to have monotonous voltage/charge characteristics (with no plateau), for example lithium-ion cells of LMO (LiMn₂O₄)/graphite type. The position of point A then depends on the cell characteristics and on the considered reference current i_{ref}, and is typically in the charge range from 20% to 60% of the nominal capacity of the cell.

For a given cell type, a characterization phase may be implemented, which enables to determine the position of point A for a reference current i_{ref} which is selected, for example, i_{ref}=0 A. A non-limiting example of a characterization method will now be described.

To begin with, a cell of the type to be characterized, having a first state of health, may be fully discharged. This cell may then be fully recharged by periodically measuring the cell voltage under current i_{ref} during the charge. The real physical charge contained in the cell may be measured all along the charge phase, for example, by means of a coulometer or of a current integrator. A measured charge value contained in the cell can thus be matched to each measured voltage value to obtain a characteristic voltage/charge value of the type shown in FIG. 1. It should be noted that if the charge current is different from i_{ref} (particularly in the case where i_{ref}=0), the current flowing through the cell may be periodically forced to value i_{ref} for a short time period, for example, shorter than 1 ms, and preferably shorter than 10 μs, corresponding to the time necessary to measure the voltage across the cell.

As a variation, the characteristic voltage/charge curve may be acquired during a phase of full discharge of the cell, rather than during a charge phase.

The cell can then be “aged” by being submitted to charge/discharge cycles representative of a typical use of the cell.

The above-mentioned steps may be repeated at least once to obtain at least a second characteristic voltage/charge curve of the type shown in FIG. 1, for at least one second cell state of health.

When at least two characteristic curves corresponding to different states of health of the cell have been recorded, point 1 may be determined based on these curves, for example, by searching for the crossing point between two characteristic curves in the charge range from 20% to 60% of the nominal cell capacity.

The measurements of the voltage according to the charge made during the characterization phase may be optionally smoothed before determining point A. As a non-limiting numerical example, points of the characteristic voltage/charge curves may be acquired at a 100-kHz frequency (one point every 10 μs), and then averaged over a sliding window of 2,000 points (20 ms).

Once the coordinates of point A are known for a cell type and a reference current i_{ref}, they may be stored by a device for managing a battery comprising elementary cells of this type.

The detection by the management device of the crossing by the battery cell of point A when the battery is in use advantageously enables the management device to reliably know the charge available in this cell, independently from possible drifts of the battery gauges due to cell aging or to other phenomena.

The battery management device is for example capable of implementing, for each battery cell, a method of detecting a crossing of point A comprising the steps of:

measuring the voltage across the cell under reference current i_{ref} at a plurality of times in a phase of cell charge or discharge between first and second state-of-charge levels, for example, between 20% and 80% of the cell SOC; and

detecting a specific predefined value U_{A} of this voltage, stored in the management device, this voltage corresponding to the voltage coordinate of point A predetermined during the characterization phase.

The charge or discharge phase of the method of detecting point A may correspond to a charge or a discharge of the cell by normal use of the battery by a system comprising the battery, for example, a power-assisted vehicle. If the normal charge or discharge current of the cell is different from reference current i_{ref}, the current crossing the cell may be periodically forced to value i_{ref} for a time period preferably sufficiently short to avoid disturbing the operation, for example, for a time period shorter than 1 ms and preferably shorter than 10 μs, corresponding to the time necessary to measure the voltage across the cell. This time period is preferably selected to be possibly identical or similar, for example equal to within 20%, to the time period for which the current is periodically forced to value i_{ref} during the characterization phase to acquire characteristic curves of the cell.

As a variation, the method of detecting point A may correspond to a dedicated cell charge or discharge phase, which may be implemented by the battery management device specifically to make the cell cross point A and thus enable to detect the crossing of point A.

As a non-limiting example, the above-mentioned method of detecting the crossing of point A by a battery cell may be used to readjust a state-of-charge gauge of the cell. The battery management device may for example implement a method of assessing the state of charge of a battery cell, this method comprising phases of estimating the state of charge of the cell and, between estimation phases, phases of readjusting the estimation method enabling to compensate for possible drifts, for example, drifts due to the cell aging or drifts of the measurements made by sensors of the management device, such readjustment phases being likely to comprise phases of detection of the crossing of point A of the cell.

As an example, a state-of-charge gauge may be readjusted after a phase of detection of a crossing of point A of the cell, to compensate for a possible difference between an estimated charge value of the cell and the real charge value known at point A, at the time of detection of point A.

An advantage is that the readjustment of a state-of-charge gauge of the cell by detection of a crossing of point A of the cell does not require a full discharge or a full charge of the cell. This enables to make the readjustment phases much less constraining than with known solutions. More frequent readjustments than in existing system may particularly be provided. This may for example enable to use state-of-charge estimation algorithms simpler than in existing systems, since a possible decrease of the reliability of the estimation algorithms may be compensated by more frequent readjustments.

The embodiments described in the present application of a method of detecting the crossing of point A of a cell, or of readjusting a state-of-charge gauge of a cell, although not limited to this specific case, are particularly advantageous for a use in a battery having a dynamically reconfigurable electric architecture. Battery having a dynamically reconfigurable electric architecture here means a battery where the electric diagram of interconnection of the elementary battery cells between the battery voltage supply terminals can be dynamically modified during the battery operation, so that an AC voltage is provided across the battery, for example to power an electric motor or any other load capable of being powered by an AC voltage. Embodiments of batteries with a dynamically reconfigurable electric architecture are for example described in patent application FR2972304, FR2972305, FR2972306, and FR2972308 of the applicant.

A battery with a dynamically reconfigurable electric architecture typically comprises a management device capable of dynamically disconnecting and reconnecting battery cells, possibly by modifying their position and/or their connection mode (series or parallel) with respect to the other battery cells, at a relatively high frequency, during battery operation phases.

Each time a cell is disconnected, the current flowing through this cell becomes zero during the disconnection period, for example in the range from 1 μs to 1 ms. Advantageously, the battery management device may exploit such frequent disconnections to implement a method of the above-mentioned type of detecting point A of the cell for a zero reference current i_{ref}. To achieve this, the management device may measure the cell voltage during cell disconnection periods belonging to the normal operation of the system until a crossing by the cell of voltage U_{A} of point A is detected. An advantage is that the detection of point A then requires no disturbance of the normal operation of the battery.

FIG. 2 illustrates in the form of blocks an embodiment of a method of readjusting a state-of-charge gauge of an elementary battery cell, which may be implemented during a cell charge or discharge phase.

In the example of FIG. 2, the readjustment method comprises a step 201 (i_{cell=i}_{ref}?) during which the management device waits for current i_{cell} flowing through the cell to cross value i_{ref}. In the case of a battery with a dynamically reconfigurable architecture, i_{ref}=0 may be selected, in which case, at step 201, if the battery is in discharge phase, the management device can wait for the next disconnection of the programmed cell to provide an AC voltage across the battery. The management device may force to value i_{ref} the current flowing through the cell, specifically to implement the readjustment method, for a sufficiently short time period to avoid significantly disturbing the normal operation of the battery, for example, for a time period shorter than 1 ms and preferably shorter than 10 μs.

When current i_{cell} is at value i_{ref}, the management device measures voltage U_{cell} across the cell at a step 202 (MEASURE U_{cell}).

At a step 203 (U_{cell}=U_{A}?), the management device monitors the crossing by voltage U_{cell} measured at step 202 of voltage value U_{A} of characteristic point A of the cell.

If, at step 203, the management device detects the crossing by the value of voltage U_{cell} measured under current i_{ref} of value U_{A}, it implements a step 204 (SOC READJUSTMENT) of readjusting the state-of-charge gauge of the cell, taking into account the difference between an estimated charge value of the cell and the known real charge value at point A, at the time of detection of point A. At the end of step 204, the readjustment method ends.

If, during step 203, the management device does not detect a crossing by the value of voltage U_{cell} measured under current i_{ref} of value U_{A}, it carries out steps 201, 202, and 203 once again.

Specific embodiments have been described. Various alterations, modifications, and improvements will readily occur to those skilled in the art.

In particular, the battery management device may optionally store, in addition to the coordinates of point A, all of one or a plurality of the characteristic voltage/charge curves of the cells at a reference current i_{ref}. In this case, to assess the state of charge of a battery cell, the management device may measure the voltage across the cell under current i_{ref}, and estimate the state of charge of the cell based on this measurement and on the stored characteristic curves. The specific curve used to estimate the state of charge of a cell may be selected by taking into account an indicator of the cell state of health.

Further, the described embodiments are not limited to the use of the method of detecting point A to readjust a state-of-charge gauge of a battery cell. The provided method may be used in any application capable of taking advantage of the knowledge, at a given time, of the real charge contained in a battery cell.

Further, during the cell characterization phase, point A may optionally be determined for a plurality of different reference currents. In this case, when the management device implements a phase of detecting the crossing by a battery cell of a point A in order to know, at a given time, the real charge contained in this cell, it may select the reference current best adapted to the use which is made of the battery during the detection phase.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of detecting a predetermined specific value of the charge contained in a first elementary cell of a battery, comprising the steps of:
measuring the voltage across the cell at a plurality of times in a phase of cell charge or discharge between first and second state-of-charge levels; and
detecting a predetermined specific value of this voltage, corresponding to the specific charge value, said specific charge and voltage values corresponding to the coordinates of a crossing point of at least two curves representative of variation of said voltage according to the charge contained in the cell, for different states of health of the cell.

2. The method of claim 1, wherein said voltage is the voltage across the cell under a reference current.

3. The method of claim 1, wherein said specific charge and voltage values correspond to the coordinates of a crossing point of at least three curves representative of the variation of said voltage according to the charge contained in the cell, for different cell states of health.

4. The method of claim 1, wherein said specific charge value is in the range from 20% to 60% of the nominal full charge capacity of the cell.

5. The method of claim 1, wherein said cell is a lithium-ion type cell and wherein said specific charge value is in the range from 38% to 42% of the nominal full charge capacity of the cell.

6. The method of claim 5, wherein said cell has a 2.2-Ah nominal capacity and a 4.2-V nominal full charge voltage, and wherein said specific voltage value is in the range from 3.5 to 3.6 V.

7. The method of claim 1, further comprising a previous characterization phase comprising acquiring, for a second elementary cell of the same type as the first cell, at least two characteristic curves representative of the variation of the voltage across the second cell according to the charge contained in the second cell, for at least two different states of health of the second cell.

8. The method of claim 7, wherein the previous characterization phase further comprises a step of determining a crossing point of said at least two characteristic curves in the charge range from 20% to 60% of the nominal capacity of the cell.

9. A method of assessing the state of charge of an elementary cell of a battery, comprising at least one phase of estimation of the state of charge of the cell by a state-of-charge estimation algorithm, and at least one phase of readjustment of the estimation algorithm, said readjustment phase comprising the steps of:
detecting a predefined specific value of the charge contained in the cell by the method of claim 1; and
readjusting the state-of-charge estimation algorithm by taking into account the difference between said specific charge value and a charge value estimated by the estimation algorithm at a time of detection of said specific charge value.

10. A system comprising:
a battery comprising a plurality of elementary cells; and
a device for managing the battery,
wherein the management device is capable of detecting the crossing by an elementary cell of a predetermined specific charge value by the method of claim 1.

11. The system of claim 10, wherein the battery is a battery with a dynamically reconfigurable architecture, and wherein the management device is capable of dynamically disconnecting and connecting back cells of the battery so that an AC voltage is provided across the battery.

12. The system of claim 11, wherein said reference current is zero and wherein said steps of measurement of the voltage across the first cell are implemented during periods of disconnection of the first cell by the management device for the generation of an AC voltage across the battery.

13. The method of claim 2, wherein said reference current is zero and wherein said steps of measurement of the voltage across the first cell are implemented during periods of disconnection of the first cell by the management device for the generation of an AC voltage across the battery.
